(19) United States
(12) Patent Application Publication
(10) Pub. No.: US 2011/0037486 A1
(43) Pub. Date: Feb. 17, 2011

(54) NUCLEOTIDE CAPACITANCE MEASUREMENT FOR LOW COST DNA SEQUENCING

(75) Inventors: Xiaoguang Zhang, Oak Ridge, TN (US); Jun-Qiang Lu, Mayaguez, PR (US)

Correspondence Address: Scully Scott Murphy & Presser PC, 400 Garden City Plaza, Suite 300, Garden City, NY, 11530, US

(73) Assignee: UT-BATTELLE, LLC, Oak Ridge, TN (US)

(21) Appl. No.: 12/848,407

(22) Filed: Aug. 2, 2010

Related U.S. Application Data
(60) Provisional application No. 61/233,662, filed on Aug. 13, 2009.

(51) Int. Cl. G01R 27/26

(52) U.S. Cl. 324/663

(57) ABSTRACT

High frequency capacitance measurement on a single strand of deoxyribonucleic acid (DNA) or a ribonucleic acid (RNA) is employed to provide identification of the nucleotides in the strand. Effect of variations in the capacitance of nucleotides can be minimized by employing statistical quantities generated from multiple measurement values on a strand of DNA or RNA nucleotides, or by employing a program that positively identifies a large capacitance nucleotide upon detection of a large capacitance. Capacitance data on a DNA strand can be used as a criterion for identifying the DNA sequence in conjunction with other methods for identifying the DNA sequence.

### CROSS REFERENCE TO RELATED APPLICATION

This application claims the benefit of priority from U.S. Provisional Application No. 61/233,662, filed on Aug. 13, 2009, the content of which in its entirety is incorporated herein by reference.

### STATEMENT REGARDING FEDERALLY SPONSORED RESEARCH OR DEVELOPMENT

This invention was made with United States government support under Prime Contract No. DE-AC05-00OR22725 awarded by the U.S. Department of Energy. The United States government has certain rights in this invention.

### FIELD OF THE INVENTION

The present invention relates to the field of DNA sequencing, and particularly to an apparatus, a system, a method, and a program for DNA sequencing through high frequency capacitance measurements.

### BACKGROUND OF THE INVENTION

Nucleotides are molecules that constitute structural units of a ribonucleic acid (RNA) and a deoxyribonucleic acid (DNA). A nucleotide molecule is composed of a nucleobase (nitrogenous base) and a five-carbon sugar (either ribose or 2′-deoxyribose), and one to three phosphate groups. Together, the nucleobase and sugar constitute a nucleoside. The phosphate groups form bonds with either the 2, 3, or 5-carbon of the sugar, the 5-carbon site being the most common. Cyclic nucleotides form when the phosphate group is bound to two of the sugar's hydroxyl groups. Ribonucleotides are nucleotides where the sugar is ribose, and deoxyribonucleotides contain the sugar deoxyribose.

Nucleotides can contain either a purine or pyrimidine base. In DNA, the purine bases are adenine and guanine, while the pyrimidines are thymine and cytosine. RNA uses uracil in place of thymine. Nucleic acids are polymeric macromolecules made from nucleotide monomers. The sequence of nucleotide molecules in a DNA or in an RNA determines the genetic information carried therein. Development of low-cost and rapid methods for sequencing DNA, in addition to its obvious medical application, can potentially enable many future breakthroughs in biological and biomedical research.

U.S. Pat. No. 6,905,586 to Lee et al. discloses an apparatus for measuring a transversal conductance when a single-stranded DNA (ssDNA) chain is threaded through a nano-gap formed by two gold (Au) nano-electrodes. In this approach, the difference in the transverse conductance between DNA nucleotides, each of which is one of adenine (A), cytosine (C), guanine (G), and thymine (T), is measured in a direct current (DC) set-up to deduce the nucleotide sequence of the single-stranded DNA under test. However, the flexibility of the ssDNA chain makes it very difficult to control the geometry of the nucleotides when they are positioned between the nano-gap, and this geometrical uncertainty can make the nucleotides indistinguishable. Averaging over geometric configurations with adequate statistics, modeled through independent molecular dynamics simulations, is one of proposed approaches to overcome the geometric noise.

An alternate approach employs nanopores to distinguish the nucleotides through their differences in size. Because of the strong correlation between the transverse conductance and the size of the nucleotides, however, the conductance measurement technique and the nanopore technique often share the same weakness, i.e., a low signal-to-noise ratio due to the large conformational disorder of the DNA bases. Modifications to electrodes and the DNA molecule itself have been proposed to improve the signal to noise ratio in DC measurements.

Sigalov, G. et al., “Detection of DNA Sequences Using an Alternating Electric Field in a Nanopore Capacitor,” Nano Lett. 8: 56-63 (2008) discloses an approach that employs nanopores. As a single-stranded DNA (ssDNA) chain passes through a nanopore, the amount of lateral deflection of each nucleotide is inversely proportional to the size of the nucleotide. As a consequence, the dipole moment of each nucleotide becomes dependent on the size of the nucleotide. In this approach, the dipole moment of the nucleotides that pass through a nanopore is measured. Sequence specific responses are identified to improve the signal-to-noise ratio. By taking advantage of the conformational distortion during DNA chain translocation through the nanopore, and by measuring the related change in the dipole moment using a GHz current, this method can produce differentiating electric signals for DNA strands composed of 25 identical nucleotides. However, refinement of this technique is needed to be able to produce differentiating signals for DNA sequences that contain a mixture of different nucleotides.

### SUMMARY OF THE INVENTION

In the present invention, high frequency capacitance measurement on a single strand of deoxyribonucleic acid (DNA) or a ribonucleic acid (RNA) is employed to provide identification of the nucleotides in the strand. Effect of variations in the capacitance of nucleotides can be minimized by employing statistical quantities generated from multiple measurement values on a strand of DNA or RNA nucleotides, or by employing a program that positively identifies a large capacitance nucleotide upon detection of a large capacitance. Capacitance data on a DNA strand can be used as a criterion for identifying the DNA sequence in conjunction with other methods for identifying the DNA sequence.

According to an aspect of the present invention, an apparatus for sequencing a nucleic acid strand is provided. The apparatus includes:

a first electrode located on a dielectric surface of a substrate;

a second electrode located on the dielectric surface of the substrate and laterally spaced from the first electrode by a gap having a width that enables a passage of a nucleic acid strand by lateral sliding; and

an AC capacitance measurement assembly connected to the first and second electrodes and configured to generate a measurement data that is functionally dependent on an AC capacitance of a test assembly including the first electrode, the second electrode, and the nucleic acid strand.

The apparatus can further include at least one nucleic acid strand transport mechanism located on the substrate and configured to slidably transport the nucleic acid strand through the gap. The at least one nucleic acid strand transport mechanism provides a linear movement of the nucleic acid strand in a direction perpendicular to the width and within a plane that is parallel to the dielectric surface.

In one embodiment, the AC capacitance measurement assembly can include an AC current source and an AC voltage measurement device, the AC current source provides a current signal across the first and second electrodes, and the AC voltage measurement device is attached to the first and second electrodes in a parallel connection with the AC current source. The measurement data can be an amplitude of an AC voltage signal across the first and second electrodes, the current signal has a predefined constant amplitude, and the AC capacitance is inversely proportional to the amplitude of the AC voltage signal.

In another embodiment, the AC capacitance measurement assembly can include an AC voltage source and an AC current measurement device, wherein the AC voltage source provides a voltage signal across the first and second electrodes, and the AC current measurement device is attached to the first and second electrodes in a series connection with the AC voltage source. The measurement data can be an amplitude of an AC current signal through the AC current measurement device, the voltage signal has a predefined constant amplitude, and the AC capacitance is proportional to the amplitude of the AC current signal.

According to another aspect of the present invention, a system for sequencing a nucleic acid strand is provided. The system includes an apparatus, a memory, and a processor device in communication with the memory. The apparatus includes a first electrode located on a dielectric surface of a substrate; a second electrode located on the dielectric surface of the substrate and laterally spaced from the first electrode by a gap having a width that enables a passage of a nucleic acid strand by lateral sliding; and an alternating current (AC) capacitance measurement assembly. The system is configured to perform a method including the steps of determining, by employing the processor device and the memory, an AC capacitance of a nucleotide molecule in the nucleic acid strand; and determining, by employing the processor device and the memory, a probability for an identity of a nucleotide base in the nucleotide molecule.

The AC capacitance of a nucleotide molecule in the nucleic acid strand can be determined by subtracting, by employing the processor device and the memory, an AC capacitance of a first structure including the first and second electrodes and not including the nucleic acid strand from another AC capacitance of a second structure including the first and second electrodes and the nucleic acid strand.

The AC capacitance of the nucleotide molecule can be determined by performing the steps of:

applying, by employing the AC capacitance assembly, an AC current signal or an AC voltage signal across the first and second electrodes; and

generating, by employing the AC capacitance assembly, a measurement data that is functionally dependent on an AC capacitance of a test assembly including the first electrode, the second electrode, and a nucleic acid strand.

The probability for the identity of the nucleotide base can be determined based on the average and a total number of measurement data on the nucleotide molecule. Alternately or in addition, the probability for the identity of the nucleotide base can be determined based on the maximum, the minimum, and a total number of measurement data on the nucleotide molecule.

The method can further include the step of slidably transporting the nucleic acid strand through the gap between generation of each of the additional measurement data, wherein the nucleotide molecule is placed between the first and second electrodes during generation of each of the additional measurement data.

According to yet another aspect of the present invention, a method for sequencing a nucleic acid is provided. The method includes:

providing an apparatus including:
a first electrode located on a dielectric surface of a substrate;
a second electrode located on the dielectric surface of the substrate and laterally spaced from the first electrode by a gap having a width that enables a passage of a nucleic acid strand by lateral sliding; and
an alternating current (AC) capacitance measurement assembly;

placing a nucleotide molecule of a nucleic acid strand within the gap;

determining, by employing the AC capacitance measurement assembly, an AC capacitance of the nucleotide molecule in the nucleic acid strand; and

determining a probability for an identity of a nucleotide base in the nucleotide molecule.

The AC capacitance of the nucleotide molecule can be determined by:

applying, by employing the AC capacitance assembly, an AC current signal or an AC voltage signal across the first and second electrodes; and

generating, by employing the AC capacitance assembly, a measurement data that is functionally dependent on an AC capacitance of a test assembly including the first electrode, the second electrode, and the nucleic acid strand, wherein the AC capacitance of the nucleotide molecule is determined based on the measurement data.

The method can further include slidably transporting the nucleic acid strand through the gap. The method can further include generating additional measurement data that is functionally dependent on the AC capacitance each time the nucleic acid strand moves through the gap, wherein the nucleotide molecule is placed between the first and second electrodes during generation of each of the additional measurement data.

The AC capacitance of the nucleotide molecule can be determined by:

generating, by employing the AC capacitance assembly, additional measurement data that is functionally dependent on the AC capacitance of the test assembly by repeating the step of applying the AC current signal or the AC voltage signal across the first and second electrodes; and

generating a statistical quantity from the measurement data and the additional measurement data; wherein the AC capacitance of the nucleotide molecule is determined by the statistical quantity.

According to still another aspect of the present invention, a machine-readable data storage device is provided. The machine-readable data storage device embodies a program of machine-executable instructions to sequence a nucleic acid employing a system. The system includes an apparatus, a memory, and a processor device in communication with the memory. The apparatus includes a first electrode located on a dielectric surface of a substrate; a second electrode located on the dielectric surface of the substrate and laterally spaced from the first electrode by a gap having a width that enables a passage of a nucleic acid strand by lateral sliding; and an alternating current (AC) capacitance measurement assembly. The program includes the steps of instructing the processor device to determine, by employing the AC capacitance measurement assembly, an AC capacitance of a nucleotide molecule in the nucleic acid strand; and instructing the processor device to determine, a probability for an identity of a nucleotide base in the nucleotide molecule.

### BRIEF DESCRIPTION OF THE DRAWINGS

It is noted that proportions of various elements in the accompanying figures are not drawn to scale to enable clear illustration of elements having smaller dimensions relative to other elements having larger dimensions.

FIG. 1A is a top-down view of a first exemplary apparatus according to a first embodiment of the present invention. An alternating current (AC) current source, an AC voltage measurement device, and electrical wiring structures are shown schematically.

FIG. 1B is a vertical cross-sectional view of the first exemplary apparatus along the plane B-B′ in FIG. 1A according to the first embodiment of the present invention.

FIG. 2A is a top-down view of a second exemplary apparatus according to a second embodiment of the present invention. An alternating current (AC) voltage source, an alternating current (AC) current measurement device, and electrical wiring structures are shown schematically.

FIG. 2B is a vertical cross-sectional view of the second exemplary apparatus along the plane B-B′ in FIG. 2A according to the second embodiment of the present invention.

FIG. 3A is a schematic drawing of a nano-gap structure between two electrodes with a nucleotide molecule. The regions labeled with different numbers are used to define the partial charges in the calculation of the molecular capacitance.

FIG. 3B is a schematic drawing of a nano-gap structure between two electrodes without a nucleotide molecule. The regions labeled with different numbers are used to define the partial charges in the calculation of the molecular capacitance.

FIG. 4A is a model of a nano-gap structure in which atoms of the electrodes and an adenine (A) molecule attached to a single strand of DNA such that the adenine (A) molecule is aligned along the y-axis to maximize the AC capacitance.

FIG. 4B is a model of a nano-gap structure in which atoms of the electrodes and an cytosine (C) molecule attached to a single strand of DNA such that the cytosine (C) molecule is aligned along the y-axis to maximize the AC capacitance.

FIG. 4C is a model of a nano-gap structure in which atoms of the electrodes and a guanine (G) molecule attached to a single strand of DNA such that the guanine (G) molecule is aligned along the y-axis to maximize the AC capacitance.

FIG. 4D is a model of a nano-gap structure in which atoms of the electrodes and an thymine (T) molecule attached to a single strand of DNA such that the thymine (T) molecule is aligned along the y-axis to maximize the AC capacitance.

FIG. 4E is a model of a nano-gap structure in which atoms of the electrodes and an adenine (A′) molecule attached to a single strand of DNA such that the adenine (A′) molecule is rotated by 90 degrees around the x-axis relative to the adenine (A) molecule in FIG. 4A.

FIG. 4F is a model of a nano-gap structure in which atoms of the electrodes and a guanine (G′) molecule attached to a single strand of DNA such that the guanine (G′) molecule is rotated by 90 degrees around the x-axis relative to the guanine (G) molecule in FIG. 4C.

FIG. 5A schematically shows a voltage profile of the nano-gap structure of FIG. 4A when each of the two electrodes has 8 Au layers.

FIG. 5B schematically shows a charge profile of the nano-gap structure of FIG. 4A when each of the two electrodes has 8 Au layers.

FIG. 6 is a graph showing molecular capacitance of an adenine molecule, a cytosine molecule, a guanine molecule, and a thymine molecule as a function of the length of the Au electrodes when aligned in an orientation that maximizes the molecular capacitance.

FIG. 7 is a graph showing molecular capacitance of an adenine molecule, a cytosine molecule, a guanine molecule, and a thymine molecule as a function of the length of the Au electrodes when aligned in an orientation that is rotated 90 degrees around the direction of a single strand DNA from the orientation that maximizes the molecular capacitance.

FIG. 8 is a graph showing average molecular capacitance of an adenine molecule, a cytosine molecule, a guanine molecule, and a thymine molecule as a function of the length of the Au electrodes. The average is taken over all possible rotational angles around the direction of a single strand DNA to which each nucleotide molecule belong.

FIG. 9 shows an exemplary apparatus according to one embodiment of the present invention.

### DETAILED DESCRIPTION OF THE INVENTION

As stated above, the present invention relates to an apparatus, a system, a method, and a program for DNA sequencing through high frequency capacitance measurements, which are now described in detail with accompanying figures. It is noted that like and corresponding elements mentioned herein and illustrated in the drawings are referred to by like reference numerals.

As defined herein, a “nucleotide base” refers to one of a cytosine, a guanine, an adenine, a thymine, and a uracil.

As defined herein, a “five-carbon sugar” refers to a ribose or a 2′-deoxyribose.

As defined herein, a “nucleoside” refers to a combination of a nucleotide base and a five-carbon sugar.

As defined herein, a “nucleotide molecule” refers to a combination of a nucleoside and one to three phosphate groups.

As defined herein, a “nucleic acid” or a “nucleic acid strand” is a plurality of nucleotide bases located on a single strand and includes single stranded DNA's and single stranded RNA's.

As defined herein, a “nucleic acid sequence” refers to a sequence of nucleotide bases in a nucleic acid.

As defined herein, a “sequencing” of a nucleic acid is an operation or an action that generates information on the nucleic acid sequence of a nucleic acid.

As defined herein, an “identity” of a nucleotide base is a composition of the nucleic base, i.e., the species of nucleic base selected from cytosine, guanine, adenine, thymine, and uracil.

As defined herein, a “nano-gap structure” is a structure having a gap between two electrodes such that the gap has a dimension, i.e., a distance between the two electrodes, from 1 nm to 10 nm.

As defined herein, a first physical quantity is “functionally dependent” on a second physical quantity is a change in said first physical quantity and a change in said second physical quantity have a one-to-one correspondence. A “functional dependence” is a state of being functionally dependent. A functional dependence includes, but is not limited to, a linear dependence, i.e., a proportional dependence, and an inversely linear dependence, i.e., an inversely proportional dependence.

As defined herein, a “memory” refers to a device, an apparatus, or a manufactured physical structure that is configured to store information and allow retrieval of the information.

As used herein, a “processor device” refers to a device, an apparatus, or a manufactured physical structure that includes an electronic circuit for processing data.

In the present invention, the electronic response of the DNA nucleotides to an alternating current (AC) field is utilized. An effective molecular capacitance is obtained by measuring the difference in a capacitance between an electrode-molecule-electrode assembly and a capacitance between the electrodes without the molecule. The effective molecular capacitance for the nucleotide molecules, calculated using a first-principles linear response model, is employed. The capacitance of the nucleotides correlates with their size. The molecular capacitance changes under conformational distortions. The capacitance of the nucleotides is in the range of 10⁻²¹ F, and produces comparable impedance as the transversal conductance in the GHz frequency range. Therefore, the AC capacitance of nucleotides, derived from GHz-frequency range electric measurement techniques, can be used as a criterion for DNA sequencing. While the present invention is described employing nucleotide molecules in DNA, embodiments in which RNA is employed instead of DNA are also contemplated herein.

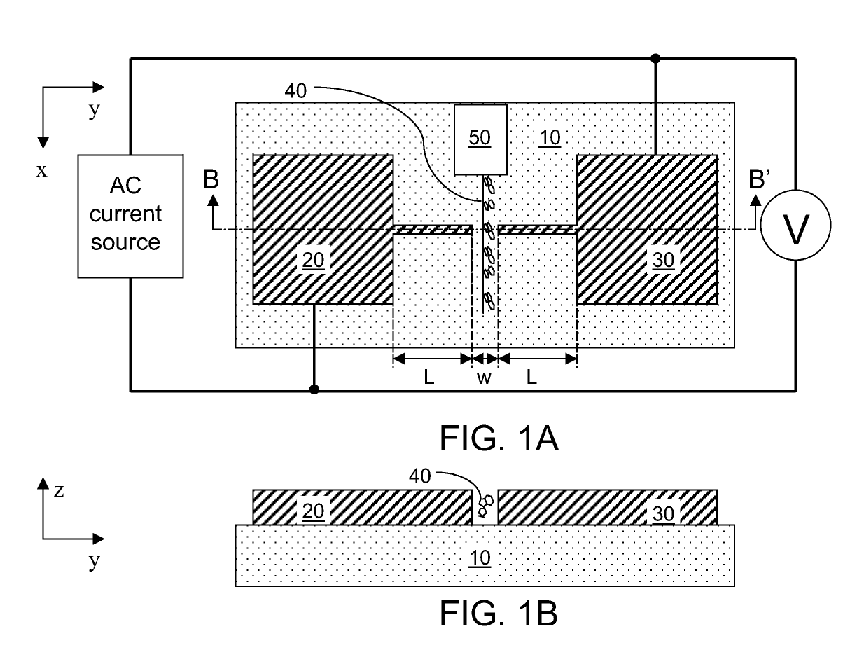

Referring to FIGS. 1A and 1B, a first exemplary apparatus according to a first embodiment of the present invention includes a substrate 10, a first electrode 20, a second electrode 30, and at least one nucleic acid strand transport mechanism 50. A nucleic acid strand 40, which can be a single strand of nucleic acid, is attached to the at least one nucleic acid strand transport mechanism 50.

The top surface of the substrate 10, on which the first and second electrodes (20, 30) are located, has a dielectric material such as silicon oxide. The dielectric material can be a hydrophobic material to minimize friction of the nucleic acid strand 40 during movement. The dielectric material at the top surface of the substrate 10 electrically isolates the first and second electrodes (20, 30) from the body of the substrate 10.

The first electrode 20 is located on a dielectric surface of a substrate 10. The second electrode 30 is located on the dielectric surface of the substrate 10, and is laterally spaced from the first electrode 20 by a gap having a width W that enables a passage of the nucleic acid strand 40 by lateral sliding.

The at least one nucleic acid strand transportation mechanism 50 is located on the substrate 10, and is configured to slidably transport the nucleic acid strand 40 through the gap, i.e., to laterally move nucleic acid strand 40 along the x-direction, which is the direction that is perpendicular to the direction connecting the first and second electrodes (20, 30). The at least one nucleic acid strand transportation mechanism 50 provides a linear movement of the nucleic acid strand 40 in a direction perpendicular to the width W and within a plane that is parallel to the dielectric surface of the substrate 10.

The first exemplary apparatus includes electrical circuit components such as an alternating current (AC) current source, an alternating current (AC) voltage measurement device represented by a voltmeter, and electrical wiring structures that connect each of the first and second electrodes (20, 30) to a node of the AC current source and the AC voltage measurement device. The alternating current (AC) current source, the alternating current (AC) voltage measurement device, and the electrical wiring structures collectively constitute an AC capacitance measurement assembly. The AC capacitance measurement assembly is connected to the first and second electrodes (20, 30), and is configured to generate a measurement data that is functionally dependent on an AC capacitance of a test assembly, which includes the first electrode 20, the second electrode 30, and the nucleic acid strand 40.

Each of the first and second electrodes (20, 30) is made of a conductive material. For example, the conductive material can be a metal such as Au, Ag, Cu, Pt, or an alloy thereof. The thickness of the first and second electrodes (20, 30), i.e., the dimension along the z-direction, can be from 1 nm to 100 nm, and preferably from 1 nm to 10 nm, although lesser and greater thicknesses can be employed also. Because the width W of the gap is a nanoscale dimension, the structure formed by the first and second electrodes (20, 30) and the gap therebetween is a nano-gap structure.

Each of the first and second electrodes (20, 30) has a protruding portion that has a length L along the y-axis. The first and second electrodes (20, 30) are spaced from each other by a gap having a width w. The width w of the gap is selected to allow passage of a nucleic acid strand. Preferably, the width w of the gap can be selected to minimize conformational distortion of the nucleic acid strand 40 during a movement along the x-direction. The width w of the gap can be from 1.2 nm to 2.4 nm, although lesser and greater widths can also be employed. Because the width of the gap is a nanoscale dimension, the gap is a nano-gap.

The length L of the protruding portions of the first and second electrodes (20, 30) can be greater than or equal to a thickness of at least one atomic layer, and can be a macroscopic dimension. The width of the protruding portions of the first and second electrodes (20, 30), as measured in the x-direction, can be a dimension corresponding to the width of a single nucleotide molecule. For example, the width of the protruding portions of the first and second electrodes (20, 30) can be from 1 nm to 2 nm, although lesser and greater widths can also be employed. Alternatively, other geometries of the first and second electrodes (20, 30) can be employed.

The at least one nucleic acid strand transport mechanism 50 can be any device that is configured to slidably attach the nucleic acid strand 40 in the x-direction, i.e., to attach the nucleic acid strand 40 in a manner that allows movement of the nucleic acid strand 40 by sliding over the top surface of the substrate 10 in the x-direction. In one embodiment, the at least one nucleic acid strand transport mechanism 50 can be configured to move in the x-direction whereby the nucleic acid strand 40 is dragged through the gap between the two electrodes (20, 30) over the top surface of the substrate 10. In another embodiment, the at least one nucleic acid strand transport mechanism 50 can be configured to include a stationary matrix over which a moving part slides so that the nucleic acid strand 40 is dragged by the moving part. In yet another embodiment, the at least one nucleic acid strand transport mechanism 50 is a plurality of nucleic acid strand transport mechanisms. For example, one nucleic acid strand transport mechanisms 50 can be separated from another nucleic acid strand transport mechanisms 50 along the x-direction so that each end of the nucleic acid strand is attached to a nucleic acid strand transport mechanism 50. In this case, one nucleic acid strand transport mechanism 50 is located on one side of the two electrodes (20, 30), and another nucleic acid strand transport mechanism 50 is located on the other side of the two electrodes (20, 30). The plurality of nucleic acid strand transport mechanisms 50 can provide a movement of the nucleic acid strand 40 back and forth along the x-direction.

Preferably, the at least one nucleic acid strand transport mechanism 50 is configured to enable multiple scanning of the nucleic acid strand 40 through the gap between the two electrodes (20, 30). Optionally, the at least one nucleic acid strand transport mechanism 50 can be provided with an azimuthal rotational capability around the x-axis so that the nucleic acid strand 40 can be scanned after a rotational movement around the x-axis.

The alternating current (AC) current source provides an alternating current signal at a frequency across the first and second electrodes (20, 30). The alternating current signal is a periodic alternating current of which the frequency of the current signal is in the range from 10 Hz to 1 THz, and preferably from 1 kHz to 300 GHz, and more preferably from 1 MHz to 100 GHz, although lesser and greater frequencies can also be employed. Because the alternating current is periodic, an identical waveform is repeated at the frequency of the alternating current. The AC current source provides an output in the form of an alternating current having a constant amplitude at a predefined high frequency. This can be effected by providing an internal feedback circuit in the AC current source so that the amplitude of the AC current from the AC current source servos to a predefined amplitude. The predefined amplitude of the alternating current can be set at a value from 1 fA to 1 μA, and typically from 1 pA to 1 nA, although lesser and greater predetermined amplitudes can also be employed.

A first output node of the AC current source is connected to the first electrode 20, and a second output node of the AC current source is connected to the second electrode 30. The AC current source can be in the form of an electronic circuit or an electronic device that delivers a predefined waveform at a selected frequency so that the output current has the predefined amplitude. For example, the predefined waveform can be a sinusoidal waveform.

The AC voltage measurement device is attached in a parallel connection with the AC current source. The AC voltage measurement device is a high frequency voltage measurement device configured to measure the amplitude of a voltage variation of a high frequency voltage signal. For example, the AC voltage measurement device can be an automated oscilloscope that is configured to determine the amplitude of a high frequency voltage input signal.

A first input node of the AC voltage measurement device is connected to the first electrode 20, and a second input node of the AC voltage measurement device is connected to the second electrode 30. The first output node of the AC current source is electrically connected to the first input node of the AC voltage measurement device, and the second output node of the AC current source is electrically connected to the second input node of the AC voltage measurement device. In a physical implementation, wiring structures can be employed to provide electrical connections. The electrical connection between an output node of the AC current source and an input node of the AC voltage measurement device can be effected by a physical contact between wiring structures, or by two wiring structures directly contacting the same electrode, i.e., one of the first and second electrodes (20, 30).

The AC voltage measurement device measures the voltage response of the first and second electrodes (20, 30) to the alternating current provided by the AC current source. The measured voltage signal at the AC voltage measurement device has the same frequency as the alternating current that the AC current source provides to the nano-gap structure. There can be a non-zero phase difference between the AC current signal from the AC current source and the AC voltage signal detected by the AC voltage measurement device. The measurement data can be an amplitude of an AC voltage signal across the first and second electrodes (20, 30), the AC current signal can have a predefined constant amplitude, and the AC capacitance can be inversely proportional to the amplitude of the AC voltage signal.

The alternating current induces charges in the nano-gap structure including the first and second electrodes (20, 30), the substrate 10, and the nucleic acid strand 40. While the amount of charge accumulated across the first and second electrodes (20, 30) is the same irrespective of the capacitance of the nano-gap structure because the amplitude of the current from the AC current source is constant, the amplitude of voltage variation across the first and second electrodes (20, 30) is inversely proportional to the capacitance of the nano-gap structure. Thus, by measuring the amplitude of the voltage across the AC voltage measurement device, the capacitance of the nano-gap structure can be calculated. Because each nucleotide molecule has a different physical structure and affects the capacitance of the nano-gap structure to a different degree, analyzing the value of the measured capacitance can determine the identity of the nucleotide molecule.

Thus, the identity of the nucleotide base within the nucleotide molecule located between the two electrodes (20, 30) can be determined by analyzing the voltage signal at the AC voltage measurement device to deduce the capacitance of the nano-gap system, which includes the nucleotide molecule as a capacitor dielectric between the two electrodes (20, 30). By moving the nucleic acid strand 40 employing the at least one nucleic acid strand transport mechanism 50, the nucleic acid strand 40 can be sequenced, i.e., the sequence of the nucleotide bases in the nucleic acid strand 40 can be determined.

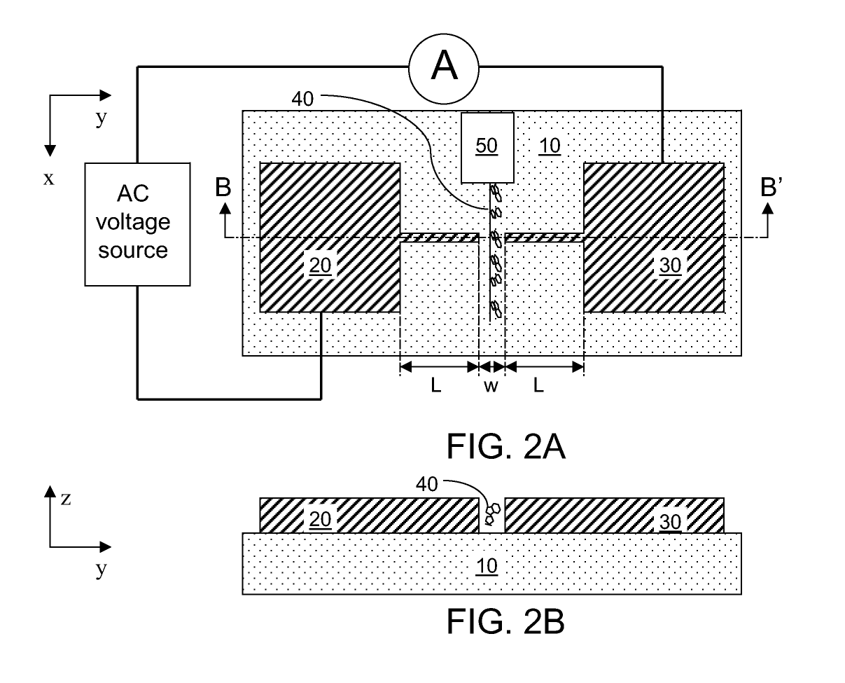

Referring to FIGS. 2A and 2B, a second exemplary apparatus according to a second embodiment of the present invention includes an alternating current (AC) voltage source, a current measurement device, and electrical wiring structures. The alternating current (AC) voltage source, the current measurement device, and the electrical wiring structures collectively constitute an AC capacitance measurement assembly. The current measurement device is an AC current measurement device, i.e., a current measurement device configured to measure AC current. The AC capacitance measurement assembly is connected to the first and second electrodes (20, 30) and is configured to generate a measurement data that is functionally dependent on an AC capacitance of a test assembly, which includes the first electrode 20, the second electrode 30, and the nucleic acid strand 40.

The alternating current (AC) voltage source provides a high frequency voltage across the first and second electrodes (20, 30). The high frequency voltage is a periodic alternating voltage of which the frequency of the voltage signal is in the range from 10 Hz to 1 THz, and preferably from 1 kHz to 300 GHz, and more preferably from 1 MHz to 100 GHz, although lesser and greater frequencies can also be employed. Thus, an identical waveform is repeated at the frequency of the high frequency voltage. The AC voltage source provides an output in the form of a high frequency voltage having a constant amplitude at a predefined high frequency. This can be effected by providing a high impedance output terminal that provides a constant amplitude for the high frequency voltage signal irrespective of the variations in the impedance of the nano-gap structure in FIGS. 2A and 2B. The predefined amplitude of the alternating current can be set at a value from 1 nV to 10 V, and typically from 1 μV to 1 mV, although lesser and greater predetermined amplitudes can also be employed.

The AC voltage source can be in the form of an electronic circuit or an electronic device that delivers a predefined waveform at a selected frequency so that the output voltage has the predefined amplitude. For example, the predefined waveform can be a sinusoidal waveform. The AC current measurement device is attached in a series connection with the AC current source. The AC current measurement device is a high frequency current measurement device configured to measure the amplitude of a current variation of a high frequency current signal. For example, the AC current measurement device can be an AC ammeter.

A first input node of the AC current measurement device is connected to an output node of the AC voltage source, and a second input node of the AC current measurement device is connected to one of the first and second electrodes (20, 30). In a physical implementation, a wiring structure can be employed to provide the electrical connection between the first input node of the AC current measurement device and an output node of the AC voltage source.

The AC current measurement device measures the current response of the first and second electrodes (20, 30) to the alternating current provided by the AC voltage source. The measured current signal at the AC current measurement device has the same frequency as the high frequency voltage that the AC voltage source provides to the nano-gap structure. There can be a non-zero phase difference between the AC voltage signal from the AC voltage source and the AC current signal detected by the AC current measurement device. The measurement data can be an amplitude of an AC current signal through the AC current measurement device, the applied voltage signal can be a predefined constant amplitude, and the AC capacitance can be proportional to the amplitude of the AC current signal.

The high frequency voltage induces charges in the nano-gap structure including the first and second electrodes (20, 30), the substrate 10, and the nucleic acid strand 40. The amount of charge accumulated across the first and second electrodes (20, 30) is proportional to the capacitance of the nano-gap structure. The amplitude of current variation measured by the AC current measurement device is proportional to the capacitance of the nano-gap structure. Thus, by measuring the amplitude of the current across the AC current measurement device, the capacitance of the nano-gap structure can be calculated. By analyzing the value of the measured capacitance, the identity of the nucleotide molecule under measurement can be determined. As in the first embodiment, by moving the nucleic acid strand 40 employing the at least one nucleic acid strand transport mechanism 50, the nucleic acid strand 40 can be sequenced.

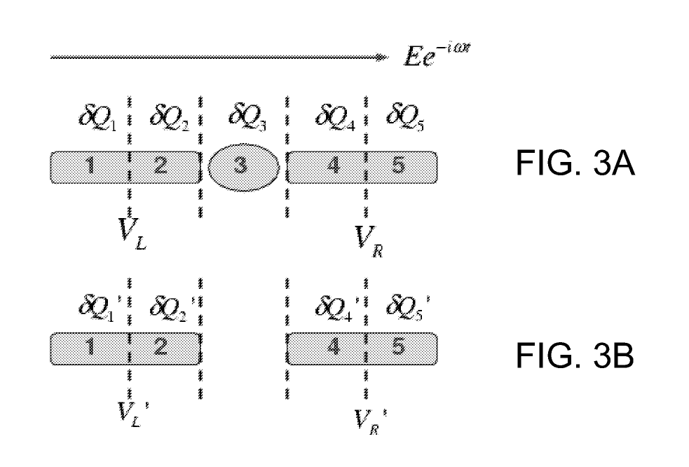

Referring to FIGS. 3A and 3B, schematics are shown for a molecular capacitance measurement setup for a nucleotide in a single strand deoxyribonucleic acid (DNA). Description of a simulation employing an atomic model is provided herein. Two electrodes are separated by a nano-gap. In FIG. 3A, a molecule is inserted into the gap between the two electrodes. In FIG. 3B, there is no molecule between the two electrodes. The two electrodes can be physically implemented as the first and second electrodes (20, 30) in the first or second exemplary apparatus in FIGS. 1A-2B.

Each electrode has a finite length, which is perpendicular to the direction of movement of the single strand DNA. This length is a parameter for the purposes of calculating the capacitance for each nucleotide until convergence is achieved. Also, this length is equivalent to the length L in FIGS. 1A and 2A. In a model, the space is divided into five regions. Each electrode is divided into two regions. Thus, the left electrode includes region 1 and region 2, and the right electrode includes region 4 and region 5. The molecule or the vacuum gap is region 3. While the models shown herein shows the electrodes having a finite length, electrodes having different geometries are also contemplated.

The spatial distribution of the electric potential is essentially uniform within the electrodes, even when the size of the electrodes is small. The voltage drop ΔV denotes the difference between the left electrode potential V_{L} and the right electrode potential V_{R} as labeled in FIG. 3A. The voltage drop ΔV′ denotes the difference between the left electrode potential V_{L}′ and the right electrode potential V_{R}′ as labeled in FIG. 3B. The linear-response in charge within each region i is defined as δQᵢ where i is 1, 2, 3, 4, and 5. The charges δQ₂, δQ₃, and δQ₄ include both first electrical charges caused by a metallic charge response from the electrodes and second electrical charges caused by the dielectric charge response from the molecule.

In principle, the capacitance of the molecules is defined with the first electrical charges caused by the metallic charge response. However, the first and second electrical charges are difficult to separate in a first-principles calculation. Because the system employed for this calculation is finite and the total net charge is always zero, the average of δQ₁ and δQ₅ can be used as the metallic charge response, i.e., the first electrical charges.

Therefore, the total capacitance C_{2,3,4} of segments 2, 3, and 4 in FIG. 3A is given by:

$${C}_{2 , 3 , 4} = \frac{δ {Q}_{1} - δ {Q}_{5}}{2 Δ V} . \qquad Equation ( 1 )$$

Similarly, the total capacitance C_{2,4} of segments 2 and 4 in FIG. 3B is given by:

$${C}_{2 , 3 , 4} = \frac{δ {Q}_{1}^{′} - δ {Q}_{5}^{′}}{2 Δ {V}^{′}} . \qquad Equation ( 2 )$$

The molecular capacitance of the single strand DNA is defined as:

C₃=C_{2,3,4}−C_{2,4}. Equation (3)

This definition leads to a converging value for C₃ with an increasing length of the electrodes. The charge response and the electric potential can be calculated using the linear response theory described in Lu, J. Q. et al., “Standing Friedel waves: a quantum probe of electronic states in nanoscale devices,” Phys. Rev. Lett. 99:226804, (2007). This method can be applied to calculate the molecular capacitance of nucleotides.

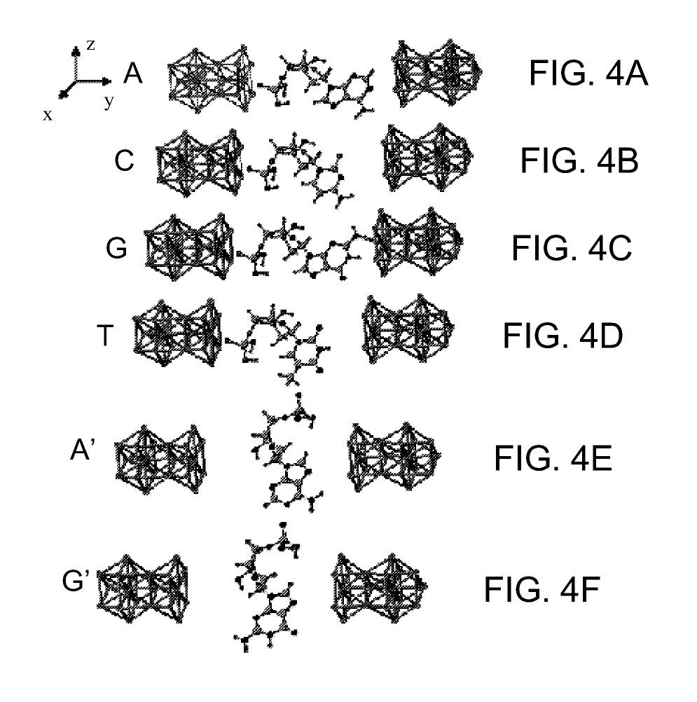

In a model employed for calculation of the molecular capacitance of nucleotides, the nucleotide molecules are placed between two electrodes as shown in FIGS. 4A-4F. In the model, the electrodes are made of Au lattices having am atomically sharp pointed ends having a nanoscale dimension. The Au electrodes are composed of alternating atomic layers in a (111) direction. Seven and three Au atoms, respectively, are present in each of the alternating layers of Au. The width W of the nano-gap, or the distance between the two Au electrodes, is set at 1.54 nm.

FIGS. 4A-4D represent configurations in an atomic model in which a nucleotide molecule is aligned in an orientation that maximizes measured AC capacitance. In this configuration, a nucleotide is located in proximity to one of the two electrodes. FIG. 4A is a model of a nano-gap structure in which atoms of the electrodes and an adenine (A) molecule attached to a single strand of DNA. The adenine (A) molecule is aligned along the y-axis to maximize the AC capacitance. FIG. 4B is a model of a nano-gap structure in which atoms of the electrodes and a cytosine (C) molecule attached to a single strand of DNA. The cytosine (C) molecule is aligned along the y-axis to maximize the AC capacitance. FIG. 4C is a model of a nano-gap structure in which atoms of the electrodes and a guanine (G) molecule attached to a single strand of DNA. The guanine (G) molecule is aligned along the y-axis to maximize the AC capacitance. FIG. 4D is a model of a nano-gap structure in which atoms of the electrodes and an thymine (T) molecule attached to a single strand of DNA. The thymine (T) molecule is aligned along the y-axis to maximize the AC capacitance.

FIGS. 4E and 4F represent configurations in an atomic model in which a nucleotide molecule is aligned in an orientation that is rotated 90 degrees around the direction of a single strand DNA from the orientation that maximizes measured AC capacitance. The direction of the single strand DNA is a horizontal direction that is perpendicular to the plane B-B′ in FIGS. 1A and 2A, i.e., corresponds to the x-direction in FIGS. 1A and 1B. In this configuration, a nucleotide is located midway between the two electrodes. FIG. 4E is a model of a nano-gap structure in which atoms of the electrodes and an adenine (A′) molecule attached to a single strand of DNA. The adenine (A′) molecule is rotated by 90 degrees around the x-axis relative to the adenine (A) molecule in FIG. 4A. FIG. 4F is a model of a nano-gap structure in which atoms of the electrodes and a guanine (G′) molecule attached to a single strand of DNA. The guanine (G′) molecule is rotated by 90 degrees around the x-axis relative to the guanine (G) molecule in FIG. 4C.

The Hamiltonian and the overlap matrices are obtained from the converged self-consistent density-functional theory (DFT) calculations, using the computational chemistry package NWChem™. B3LYP exchange-correlation function, which is usually believed to work better for organic molecules, can be employed. Further, the Gaussian basis based on the CRENBL-effective core potentials (ECP), with 16 (4s4p) functions for each atom of N, C, O, and P and 4 (4s) functions for each H, can be employed. Also, CRENBS-ECP spherical basis consisting of 9 (1s1p1d) functions for each atom can be used for Au.

Once the Hamiltonian and the overlap matrices are extracted from the DFT calculations, the linear response theory and Equations (1), (2), and (3) are applied to calculate the molecular capacitance of a single strand DNA.

In the model, the applied external alternating current (AC) field E^{iωt} is along the electrode direction, i.e., in a horizontal direction that is perpendicular to the direction of movement of the single strand DNA, with an amplitude the electric field E at 1 mV/nm and the angular frequency ω=2πf at 16 GHz. Since the calculation is within the linear-response regime, the amplitude of the electric field has no effect on the results. Likewise, the frequency is sufficiently low to avoid any resonance frequencies so that there is no dependence of the results on the frequency.

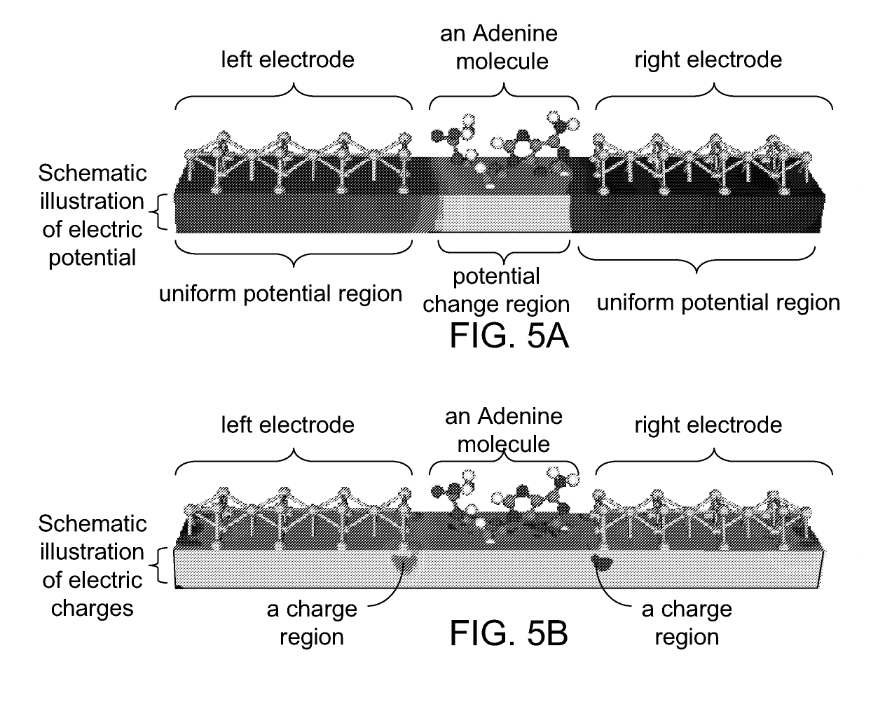

Referring to FIG. 5A, an electric potential profile of a model nano-gap system is schematically shown in juxtaposition with atoms representing Au atoms in a pair of electrodes and atoms representing an adenine molecule, i.e., a nucleotide A, which is a nucleotide molecule, located between the two electrodes. In this model nano-gap system, each of the electrodes is composed of eight Au layers, i.e., has a length of 8 atomic Au layers. The electric potential inside each electrode is essentially flat, despite the small size of the electrodes in this calculation. Most of the voltage drop occurs over the nucleotide molecule.

Referring to FIG. 5B, a charge response of the model nano-gap system is schematically shown. The charge response occurs mostly at the two ends of both electrodes, which are marked as “a charge region.” A small charge response occurs within the nucleotide A. The charge response in the middle sections of both electrodes is insignificant. Thus, the method of dividing each electrode into two half sections and using only the outside charge for calculating the molecular capacitance is justified.

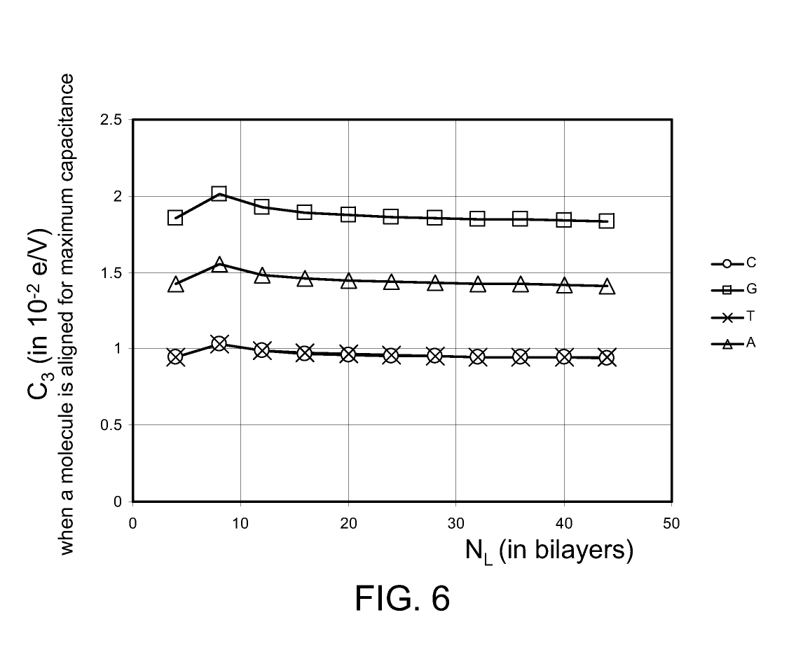

Referring to FIG. 6, the convergence of the molecular capacitance for all four nucleotide molecules as a function of the length L of the two electrodes in terms of the number of atomic Au layers in each electrode is shown according to a simulation result. The geometry of the electrodes and the nucleic molecules is as shown in FIGS. 4A-4D. The molecular capacitance is sufficiently converged when the length of the electrodes in number N_{L} of atomic Au layers reaches 88. The converged molecular capacitance for the nucleotide molecules are, 1.84×10⁻² e/V for G, 1.41×10⁻² e/V for A, and 0.94×10⁻² e/V for both C and T. 1 e/V is equal to 1.6×10⁻¹⁹ F.

Therefore the nucleotides A and G can be distinguished from nucleotides C and T through the molecular capacitance measurement. The values of the capacitance can be compared to the capacitance of a parallel plate capacitor, which is given by ∈∈₀A/d, where A is the cross section area of electrodes, d is the width of the gap, ∈₀ is the permittivity of vacuum having a value of 8.85×10⁻¹² F/m, ∈ is the effective dielectric constant of a dielectric material between the two electrodes. If the values of A and d are set at 0.1 nm² and 1.5 nm, respectively, then the effective dielectric constant is approximately between 2 and 5 for these molecules.

Conformational fluctuation of the nucleotide molecules affects measured values of the molecular capacitance. For the four nucleotide molecules, the extreme case in which each nucleotide molecules are rotated by 90 degrees around the x-axis are examined. For an adenine molecule, this geometry corresponds to FIG. 4E in which an adenine molecule with a 90 degree rotation around the x-axis is labeled as A′. For a guanine molecule, this geometry corresponds to FIG. 4F in which an adenine molecule with a 90 degree rotation around the x-axis is labeled as G′. The configuration with the 90 degree rotation is expected to give the smallest capacitance for the each nucleotide molecule since the atoms in the molecule are the farthest away from either electrode.

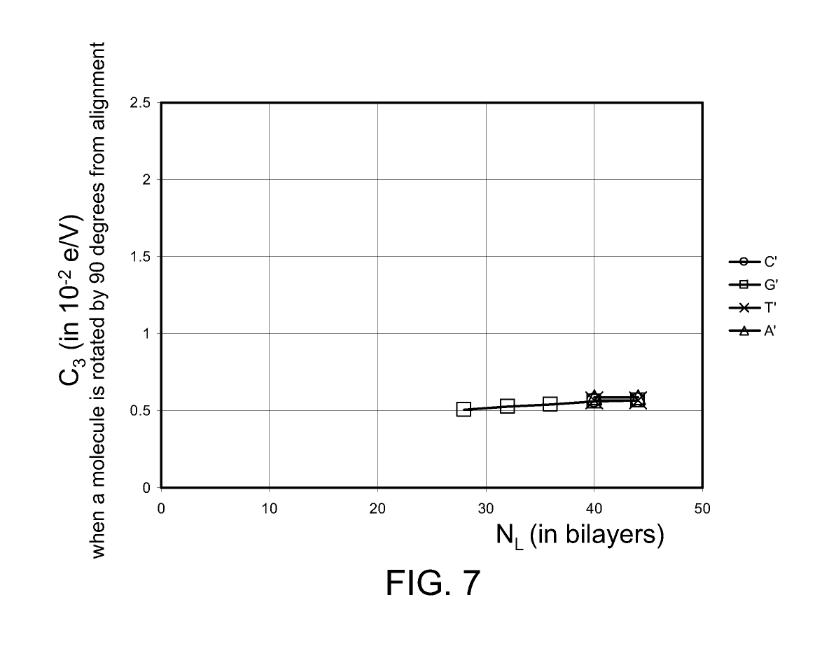

Referring to FIG. 7, the calculated molecular capacitance is shown for all four nucleotide molecules placed in a geometric arrangement of the type employed in FIGS. 4E and 4F according to a simulation result. The calculated molecular capacitance is shown as a function of the length L for each type of nucleotide base. The calculated values for the capacitance of nucleotide molecules are clustered around the value of about 0.57×10⁻² e/V for all four nucleotide molecules. At N_{L}=88, the calculated molecular capacitances are 0.59×10⁻² e/V for A′, i.e., for an adenine molecule with a 90 degree rotation around a lengthwise direction of a nucleic strand (corresponding to the x-axis in FIGS. 1A and 1B), and 0.57×10⁻² e/V for G′, i.e., for a guanine molecule with a 90 degree rotation around the lengthwise direction of the nucleic strand.

The calculated molecular capacitance distinguishes G and A from C and T. Similar to direct current (DC) transverse conductance measurements, the molecular capacitance also sorts the nucleotides according to their sizes. However, unlike a tunneling conductance, the molecular capacitance is not exponentially sensitive to the conformational disorder. Thus, the effect of conformational disorder on the measured values of AC capacitance measurements is less than the corresponding effect of conformational disorder on measured values of DC tunneling conductance measurement. By averaging over multiple AC capacitance measurements, a better signal-to-noise ratio is provided than the similar averaging on tunneling conductance measurements.

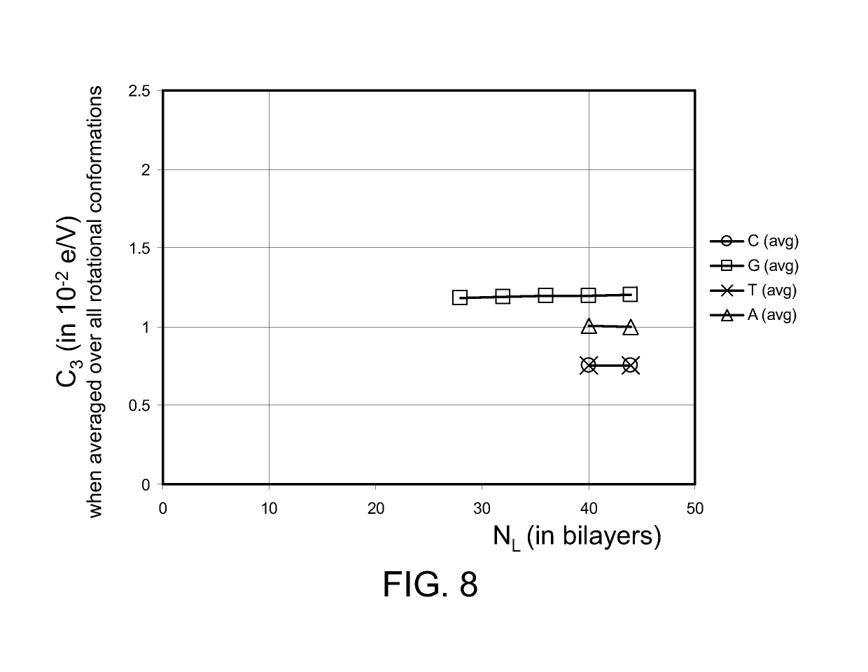

Referring to FIG. 8, calculated average values from an ensemble of measurements, in which the conformational disorder is randomized, are shown for each nucleotide molecule according to a simulation result. Repeating an AC capacitance measurement on the same nucleotide molecule can generate such an ensemble of measurements. Thus, a guanine molecule is statistically distinguishable from an adenine molecule, a cytosine molecule, and a thymine molecule. Likewise, an adenine molecule is statistically distinguishable from a guanine molecule, a cytosine molecule, and a thymine molecule.

The first or second exemplary apparatus can be employed to sequence a nucleic acid strand employing the methods described above. Thus, a nucleotide molecule of a nucleic acid strand can be placed within the gap in the first or second exemplary apparatus. Employing the AC capacitance measurement assembly, an AC capacitance of the nucleotide molecule in the nucleic acid strand can be determined. Then, the probability for an identity of a nucleotide base in the nucleotide molecule can be determined. The AC capacitance assembly can be employed to apply an AC current signal or an AC voltage signal across the first and second electrodes. This step can be effected by a program in a computer that instructs the AC capacitance assembly to apply an AC current signal or an AC voltage signal across the first and second electrodes. Further, the AC capacitance assembly can be employed to generate a measurement data that is functionally dependent on an AC capacitance of a test assembly including the first electrode 20, the second electrode 30, and the nucleic acid strand 40 (See FIGS. 1A-2B). The program can instructs the AC capacitance assembly to generate a measurement data that is functionally dependent on an AC capacitance of a test assembly including the first electrode, the second electrode, and a nucleic acid strand. The AC capacitance of the nucleotide molecule is determined based on the measurement data.

The AC capacitance assembly can be employed, in conjunction with a processor device an a memory of a computer, to generate additional measurement data that is functionally dependent on the AC capacitance of the test assembly by repeating the step of applying the AC current signal or the AC voltage signal across the first and second electrodes. Further, the AC capacitance assembly can be employed, in conjunction with a processor device an a memory of a computer, to generate a statistical quantity from the measurement data and the additional measurement data. The AC capacitance of the nucleotide molecule can be determined by the statistical quantity. As described above, the nucleic acid strand can be slidably transported through the gap between generation of each of the additional measurement data. The nucleotide molecule can be placed between the first and second electrodes during generation of each of the additional measurement data.

In one embodiment, the AC capacitance measurement assembly can include an AC current source and an AC voltage measurement device. In this case, the AC voltage measurement device is attached to the first and second electrodes in a parallel connection with the AC current source. The AC current source, optionally by employing a program that includes the step of instructing the AC current source, can be employed to apply an AC current signal across the first and second electrodes (20, 30; See FIGS. 1A-1B). The measurement data is an amplitude of an AC voltage signal across the first and second electrodes, and the AC capacitance is inversely proportional to the amplitude of the AC voltage signal.

In another embodiment, the AC capacitance measurement assembly can include an AC voltage source and an AC current measurement device. In this case, the AC current measurement device is attached to the first and second electrodes in a series connection with the AC voltage source. The AC voltage source, optionally by employing a program that includes the step of instructing the AC voltage source, can be employed to apply an AC voltage signal across the first and second electrodes (20, 30; See FIGS. 2A-2B). The measurement data is an amplitude of an AC current signal through the AC current measurement device, and the AC capacitance is proportional to the amplitude of the AC current signal.

Additional measurement data that is functionally dependent on the AC capacitance can be generated each time the nucleic acid strand moves through the gap such that the nucleotide molecule is placed between the first and second electrodes during generation of each of the additional measurement data. The initial and additional measurement data on each nucleotide molecule generates a statistical ensemble of measurement data on AC capacitance of the nucleotide molecule, which can be analyzed by statistical methods. The measurement can be repeated for each nucleotide molecule in a nucleic acid strand.

Statistical deviations from the average values for the AC capacitance of each nucleotide molecules can be calculated for a given number of repeated measurements. For example, the number of repeated measurements can be from 10 to 100, although lesser and greater number of repetitions can also be employed. Thus, given an average value for AC capacitance of a nucleotide molecule, probabilities can be assigned for the tested nucleotide molecule to be any one of the four types of nucleotide molecules. For example, if the average value for AC capacitance from 10 measurements is above 1.3×10⁻² e/V, the probability for the tested nucleotide molecule to be a guanine molecule is close to 1.0. If the average value for AC capacitance from 10 measurements is below 0.75×10⁻² e/V, the probability for the tested nucleotide molecule to be a cytosine molecule is close to 0.5 and the probability for the tested nucleotide molecule to be a thymine molecule is also close to 0.5

Other statistical quantities than the average from an ensemble of AC capacitance measurement values can also be employed. For example, given a maximum value from an ensemble of AC capacitance measurement values and the total number of measurements in the ensemble, the probability that the measured nucleotide is a particular molecule can be calculated. For example, if the maximum of AC capacitance measurement values in an ensemble of 10 measurement values is 1.8×10⁻² e/V, the probability for the tested nucleotide molecule to be a guanine molecule is close to 1.0. If the maximum of AC capacitance measurement values in an ensemble of 30 measurement values is 1.4×10⁻² e/V, the probability for the tested nucleotide molecule to be an adenine molecule is close to 1.0, and the probability for the tested nucleotide molecule to be a guanine is a small non-zero number. If the maximum of AC capacitance measurement values in an ensemble of 100 measurement values is 0.9×10⁻² e/V, the probability for the tested nucleotide molecule to be a cytosine molecule is close to 0.5, and the probability for the tested nucleotide molecule to be a thymine molecule is close to 0.5, and the probability for the tested nucleotide molecule to be an adenine molecule or a guanine molecule is a small non-zero number.

Alternately, a quantile distribution of values in an ensemble of AC capacitance measurement values can be analyzed to calculate, or assign, the probability for the tested nucleic molecule to be a particular type of nucleic molecule. In general, given an ensemble of AC capacitance measurement values on a nucleotide molecule, probabilities for the tested nucleotide molecule to be any one of the four types of nucleotide molecule can be assigned either by analyzing the average for the AC capacitance measurement values, a maximum of the AC capacitance measurement values, or any other statistical quantities.

The statistical quantities that can be employed to determine the identity of a nucleotide base in a nucleotide molecule include, but are not limited to, an average, a standard deviation, a maximum, a minimum, and a quantile. For example, the probability for the identity of the nucleotide base can be determined based on the average and a total number of measurement data on the nucleotide molecule. Alternately or in parallel, the probability for the identity of the nucleotide base can be determined based on the maximum, the minimum, and a total number of measurement data on the nucleotide molecule.

By the combination of repeated AC capacitance measurements and assignment of probabilities for the identity of the tested nucleotide molecules, the sequencing of a single strand DNA can be facilitated. The AC capacitance measurement can be made repeatedly and reliably in a relatively short time, thereby functioning as an inexpensive tool to help identify the sequence of nucleotide molecules in a tested single strand DNA. By employing statistical methods, the uncertainty can be reduced in the identity of the nucleotide molecules that are introduced by conformational disorder and/or the proximity of capacitance values between cytosine and thymine.

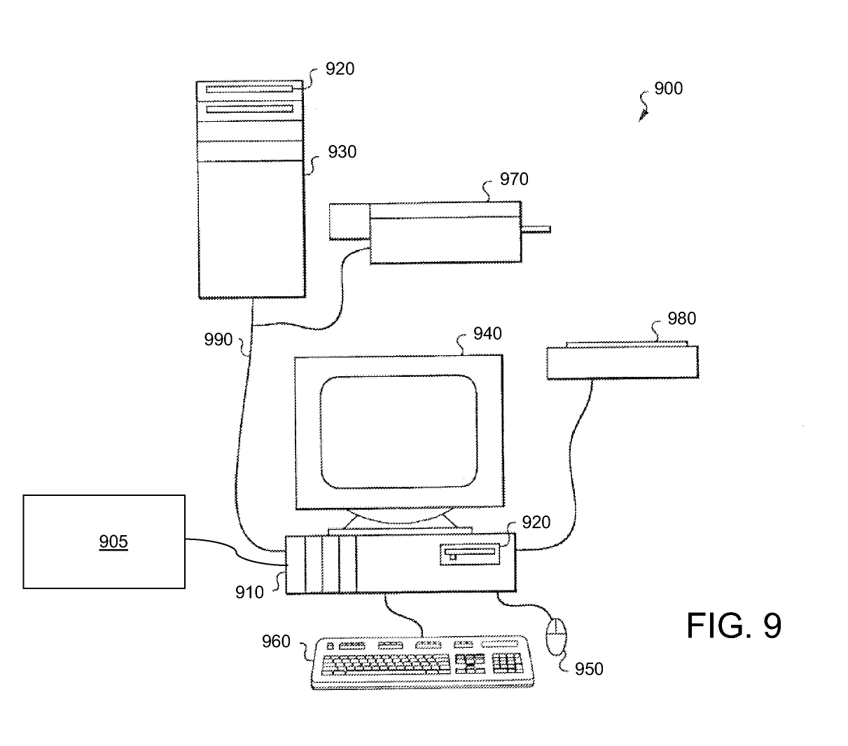

Referring to FIG. 9, an exemplary system 900 according to the present invention is shown. The exemplary system 900 can be employed to extract information on the identity of nucleotides from a single stranded DNA. The exemplary system includes a computing device that is configured to perform program instructions. The computing device can include a memory and a processor device in communication with the memory. The program instructions can configure the computing device to perform the steps of embodiments of the present invention described above. The exemplary system 900 can be a computer-based system in which the methods of the embodiments of the invention can be carried out by an automated program of machine-executable instructions to generate information on capacitance of nucleotides that pass through a space between a pair of electrodes separated by a nanoscale distance.

The computer-based system includes a processing unit 910, which can be a computing device and houses a processor device, a memory and other systems components (not shown expressly in the drawing) that implement a general purpose or special purpose processing system, or can be a computer that can execute a computer program product. The computer program product can comprise data storage media, such as a compact disc, which can be read by the processing unit 910 through a disc drive 920. Alternately or in addition, the data storage media can be read by any means known to the skilled artisan for providing the computer program product to the general purpose processing system to enable an execution thereby. The exemplary system 900 can include an apparatus 905 for measuring alternate current (AC) capacitance of nucleotides from a single strand DNA as described above. For example, the apparatus 905 can be the first exemplary apparatus shown in FIGS. 1A and 1B or the second exemplary apparatus shown in FIGS. 2A and 2B.

The exemplary system can be employed to sequence a nucleic acid strand. The system includes at least the apparatus 905, a memory, and a processor device in communication with the memory. The memory and the processor device are provided within the processing unit 910. The exemplary system can be configured to perform a method including the steps of determining, by employing the processor device and the memory, an AC capacitance of a nucleotide molecule in the nucleic acid strand; and determining, by employing the processor device and the memory, a probability for an identity of a nucleotide base in the nucleotide molecule.

The AC capacitance of a nucleotide molecule in the nucleic acid strand can be determined by subtracting, by employing the processor device and the memory, an AC capacitance of a first structure including the first and second electrodes and not including the nucleic acid strand from another AC capacitance of a second structure including the first and second electrodes and the nucleic acid strand. The method of subtraction is the method of determining C₃ described above, i.e., subtracting an AC capacitance of a first structure including the first and second electrodes and not including the nucleic acid strand from another AC capacitance of a second structure including the first and second electrodes and the nucleic acid strand to determine the AC capacitance of a nucleotide molecule in the nucleic acid strand.

Statistical analysis can be performed employing the processor device and the memory by providing instructions to the processor device employing the program. Further, the processor device can be instructed to determine a probability for the nucleotide base being an adenine, a probability for the nucleotide base being a cytosine, a probability for the nucleotide base being a guanine, and a probability for the nucleotide base being a thymine or a uracil.

A data storage device that is programmable and readable by a machine and tangibly embodying or storing a program of machine-executable instructions that are executable by the machine to perform the methods described herein are also provided. For example, the automated program can be embodied, i.e., stored, in a machine-readable data storage devices such as a hard disk, a CD ROM, a DVD ROM, a portable storage device having an interface such as a USB interface, a magnetic disk, or any other storage medium suitable for storing digital data. The program of machine-executable instructions can be employed to sequence a nucleic acid employing a system of the present invention.

The computer program product can comprise all the respective features enabling the implementation of the inventive method described herein, and which is able to carry out the method when loaded in a computer system. Computer program, software program, program, or software, in the present context means any expression, in any language, code or notation, of a set of instructions intended to cause a system having an information processing capability to perform a particular function either directly or after either or both of the following: (a) conversion to another language, code or notation; and/or (b) reproduction in a different material form.

The computer program product can be stored on hard disk drives within the processing unit 910, as mentioned, or can be located on a remote system such as a server 930, coupled to the processing unit 910, via a network interface such as an Ethernet interface. A monitor 940, a mouse 950 and a keyboard 960 are coupled to the processing unit 910, to provide user interaction. A scanner 980 and a printer 970 can be provided for document input and output. The printer 970 is shown coupled to the processing unit 910 via a network connection, but can be coupled directly to the processing unit 910. The scanner 980 is shown coupled to the processing unit 910 directly, but it should be understood that peripherals might be network coupled, or direct coupled without affecting the ability of the processing unit 910 to perform the method of the invention.

While the invention has been described in terms of specific embodiments, it is evident in view of the foregoing description that numerous alternatives, modifications and variations will be apparent to those skilled in the art. All publications, patents, and patent applications cited herein are incorporated by reference in their entirety for all purposes to the same extent as if each individual publication, patent, or patent application were specifically and individually indicated to be so incorporated by reference. Accordingly, the invention is intended to encompass all such alternatives, modifications and variations which fall within the scope and spirit of the invention and the following claims.

What is claimed is:

1. An apparatus for sequencing a nucleic acid strand, said apparatus comprising:
a first electrode located on a dielectric surface of a substrate;
a second electrode located on said dielectric surface of said substrate and laterally spaced from said first electrode by a gap having a width that enables a passage of a nucleic acid strand by lateral sliding; and
an AC capacitance measurement assembly connected to said first and second electrodes and configured to generate a measurement data that is functionally dependent on an AC capacitance of a test assembly including said first electrode, said second electrode, and said nucleic acid strand.

2. The apparatus of claim 1, further comprising at least one nucleic acid strand transport mechanism located on said substrate and configured to slidably transport said nucleic acid strand through said gap.

3. The apparatus of claim 2, wherein said at least one nucleic acid strand transport mechanism provides a linear movement of said nucleic acid strand in a direction perpendicular to said width and within a plane that is parallel to said dielectric surface.

4. The apparatus of claim 1, wherein said AC capacitance measurement assembly includes an AC current source and an AC voltage measurement device, said AC current source provides a current signal across said first and second electrodes, and said AC voltage measurement device is attached to said first and second electrodes in a parallel connection with said AC current source.

5. The apparatus of claim 4, wherein said current signal is a periodic alternating current having a frequency in the range from 10 Hz to 1 THz.

6. The apparatus of claim 5, wherein said periodic alternating current has a sinusoidal waveform.

7. The apparatus of claim 4, wherein said measurement data is an amplitude of an AC voltage signal across said first and second electrodes, said current signal has a predefined constant amplitude, and said AC capacitance is inversely proportional to said amplitude of said AC voltage signal.

8. The apparatus of claim 1, wherein said AC capacitance measurement assembly includes an AC voltage source and an AC current measurement device, said AC voltage source provides a voltage signal across said first and second electrodes, and said AC current measurement device is attached to said first and second electrodes in a series connection with said AC voltage source.

9. The apparatus of claim 8, wherein said voltage signal is a periodic alternating voltage having a frequency in the range from 10 Hz to 1 THz.

10. The apparatus of claim 9, wherein said periodic alternating voltage has a sinusoidal waveform.

11. The apparatus of claim 8, wherein said measurement data is an amplitude of an AC current signal through said AC current measurement device, said voltage signal has a predefined constant amplitude, and said AC capacitance is proportional to said amplitude of said AC current signal.

12. The apparatus of claim 1, wherein said width is from 1.2 nm to 2.4 nm.

13. The apparatus of claim 1, wherein each of said first and second electrodes includes a protruding portion having an end surface at one end of said gap, wherein said protruding portion has a width from 1 nm to 2 nm.

14. A system for sequencing a nucleic acid strand, said system comprising an apparatus, a memory, and a processor device in communication with said memory, wherein said apparatus comprises:
a first electrode located on a dielectric surface of a substrate;
a second electrode located on said dielectric surface of said substrate and laterally spaced from said first electrode by a gap having a width that enables a passage of a nucleic acid strand by lateral sliding; and
an alternating current (AC) capacitance measurement assembly;
and wherein said system is configured to perform a method comprising the steps of:
determining, by employing said processor device and said memory, an AC capacitance of a nucleotide molecule in said nucleic acid strand; and
determining, by employing said processor device and said memory, a probability for an identity of a nucleotide base in said nucleotide molecule.

15. The system of claim 14, wherein said apparatus further comprises at least one nucleic acid strand transport mechanism located on said substrate and configured to slidably transport said nucleic acid strand through said gap, and wherein said system is configured to repeat said method for each nucleotide molecule in said nucleic acid strand each time said nucleic acid strand moves through said gap.

16. The system of claim 14, wherein said AC capacitance of a nucleotide molecule in said nucleic acid strand is determined by subtracting, by employing said processor device and said memory, an AC capacitance of a first structure including said first and second electrodes and not including said nucleic acid strand from another AC capacitance of a second structure including said first and second electrodes and said nucleic acid strand.

17. The system of claim 14, wherein said AC capacitance of said nucleotide molecule is determined by performing the steps of:
applying, by employing said AC capacitance assembly, an AC current signal or an AC voltage signal across said first and second electrodes; and
generating, by employing said AC capacitance assembly, a measurement data that is functionally dependent on an AC capacitance of a test assembly including said first electrode, said second electrode, and a nucleic acid strand.

18. The system of claim 17, wherein said AC capacitance of said nucleotide molecule is determined by further performing the steps of:
generating, by employing said AC capacitance assembly, additional measurement data that is functionally dependent on said AC capacitance of said test assembly by repeating said step of applying said AC current signal or said AC voltage signal across said first and second electrodes; and
generating, by employing said processor device and said memory, a statistical quantity from said measurement data and said additional measurement data; wherein said AC capacitance of said nucleotide molecule is determined by said statistical quantity.

19. The system of claim 18, wherein said statistical quantity includes at least one of an average, a standard deviation, a maximum, a minimum, and a quantile.

20. The system of claim 19, wherein said probability for said identity of said nucleotide base is determined based on said average and a total number of measurement data on said nucleotide molecule.

21. The system of claim 19, wherein said probability for said identity of said nucleotide base is determined based on said maximum, said minimum, and a total number of measurement data on said nucleotide molecule.

22. The system of claim 18, wherein method further comprises the step of slidably transporting said nucleic acid strand through said gap between generation of each of said additional measurement data, wherein said nucleotide molecule is placed between said first and second electrodes during generation of each of said additional measurement data.

23. The system of claim 14, wherein said AC capacitance measurement assembly includes an AC current source and an AC voltage measurement device, said AC voltage measurement device is attached to said first and second electrodes in a parallel connection with said AC current source, said method comprises applying, employing said AC current source, said AC current signal across said first and second electrodes, said measurement data is an amplitude of an AC voltage signal across said first and second electrodes, and said AC capacitance is inversely proportional to said amplitude of said AC voltage signal.

24. The system of claim 14, wherein said AC capacitance measurement assembly includes an AC voltage source and an AC current measurement device, said AC current measurement device is attached to said first and second electrodes in a series connection with said AC voltage source, said method comprises applying, employing said AC voltage source, a voltage signal across said first and second electrodes, said measurement data is an amplitude of an AC current signal through said AC current measurement device, and said AC capacitance is proportional to said amplitude of said AC current signal.

25. The system of claim 14, wherein said step of determining said probability for said identity includes determining, by employing said processor device and said memory, a probability for said nucleotide base being an adenine, a probability for said nucleotide base being a cytosine, a probability for said nucleotide base being a guanine, and a probability for said nucleotide base being a thymine or a uracil.

26. A method for sequencing a nucleic acid strand, said method comprising:
providing an apparatus including:
a first electrode located on a dielectric surface of a substrate;
a second electrode located on said dielectric surface of said substrate and laterally spaced from said first electrode by a gap having a width that enables a passage of a nucleic acid strand by lateral sliding; and
an alternating current (AC) capacitance measurement assembly;
placing a nucleotide molecule of a nucleic acid strand within said gap;
determining, employing said AC capacitance measurement assembly, an AC capacitance of said nucleotide molecule in said nucleic acid strand; and
determining a probability for an identity of a nucleotide base in said nucleotide molecule.

27. The method of claim 26, wherein said AC capacitance of said nucleotide molecule is determined by performing the steps of:
applying, by employing said AC capacitance assembly, an AC current signal or an AC voltage signal across said first and second electrodes; and
generating, by employing said AC capacitance assembly, a measurement data that is functionally dependent on an AC capacitance of a test assembly including said first electrode, said second electrode, and said nucleic acid strand, wherein said AC capacitance of said nucleotide molecule is determined based on said measurement data.

28. The method of claim 27, wherein said AC capacitance of said nucleotide molecule is determined while slidably transporting said nucleic acid strand through said gap.

29. The method of claim 28, wherein said AC capacitance of said nucleotide molecule is determined by performing the step of generating additional measurement data that is functionally dependent on said AC capacitance each time said nucleic acid strand moves through said gap, wherein said nucleotide molecule is placed between said first and second electrodes during generation of each of said additional measurement data.

30. The method of claim 26, wherein said AC capacitance of said nucleotide molecule is determined by performing the step of subtracting an AC capacitance of a first structure including said first and second electrodes and not including said nucleic acid strand from another AC capacitance of a second structure including said first and second electrodes and said nucleic acid strand to determine said AC capacitance of a nucleotide molecule in said nucleic acid strand.

31. The method of claim 26, wherein said AC capacitance of said nucleotide molecule is determined by performing the steps of:
generating, by employing said AC capacitance assembly, additional measurement data that is functionally dependent on said AC capacitance of said test assembly by repeating said step of applying said AC current signal or said AC voltage signal across said first and second electrodes; and
generating a statistical quantity from said measurement data and said additional measurement data; wherein said AC capacitance of said nucleotide molecule is determined by said statistical quantity.

32. The method of claim 31, wherein said statistical quantity includes at least one of an average, a standard deviation, a maximum, a minimum, and a quantile.

33. The method of claim 26, wherein said AC capacitance measurement assembly includes an AC current source and an AC voltage measurement device, said AC voltage measurement device is attached to said first and second electrodes in a parallel connection with said AC current source, said method comprises applying, employing said AC current source, said AC current signal across said first and second electrodes, said measurement data is an amplitude of an AC voltage signal across said first and second electrodes, and said AC capacitance is inversely proportional to said amplitude of said AC voltage signal.

34. The method of claim 26, wherein said AC capacitance measurement assembly includes an AC voltage source and an AC current measurement device, said AC current measurement device is attached to said first and second electrodes in a series connection with said AC voltage source, said method comprises applying, employing said AC voltage source, a voltage signal across said first and second electrodes, said measurement data is an amplitude of an AC current signal through said AC current measurement device, and said AC capacitance is proportional to said amplitude of said AC current signal.

35. The method of claim 26, said step of determining said probability for said identity is effected by performing a step of determining, by employing said processor device and said memory, a probability for said nucleotide base being an adenine, a probability for said nucleotide base being a cytosine, a probability for said nucleotide base being a guanine, and a probability for said nucleotide base being a thymine or a uracil.

36. A machine-readable data storage device embodying a program of machine-executable instructions to sequence a nucleic acid strand employing a system, said system comprising an apparatus, a memory, and a processor device in communication with said memory, wherein said apparatus comprises:
a first electrode located on a dielectric surface of a substrate;
a second electrode located on said dielectric surface of said substrate and laterally spaced from said first electrode by a gap having a width that enables a passage of a nucleic acid strand by lateral sliding; and
an alternating current (AC) capacitance measurement assembly;
and wherein said program comprises the steps of:
instructing said processor device to determine, by employing said AC capacitance measurement assembly, an AC capacitance of a nucleotide molecule in said nucleic acid strand; and
instructing said processor device to determine, a probability for an identity of a nucleotide base in said nucleotide molecule.

37. The machine-readable data storage device of claim 36, wherein said apparatus further comprises at least one nucleic acid strand transport mechanism located on said substrate and configured to slidably transport said nucleic acid strand through said gap, and wherein said program further comprises the step of instructing said AC capacitance assembly to generate a measurement data for each nucleotide molecule in said nucleic acid strand each time said nucleic acid strand moves through said gap.

38. The machine-readable data storage device of claim 36, wherein said AC capacitance of said nucleotide molecule is determined through instructing said processor device to subtract, by employing said memory, an AC capacitance of a first structure including said first and second electrodes and not including said nucleic acid strand from another AC capacitance of a second structure including said first and second electrodes and said nucleic acid strand.

39. The machine-readable data storage device of claim 36, wherein said program further comprises the steps of:
instructing said AC capacitance assembly to apply an AC current signal or an AC voltage signal across said first and second electrodes; and
instructing said AC capacitance assembly to generate a measurement data that is functionally dependent on an AC capacitance of a test assembly including said first electrode, said second electrode, and a nucleic acid strand.

40. The machine-readable data storage device of claim 39, wherein said program further comprises the steps of:
instructing said AC capacitance assembly to generate additional measurement data that is functionally dependent on said AC capacitance of said test assembly by repeating said step of applying said AC current signal or said AC voltage signal across said first and second electrodes; and
instructing said processor device to generate a statistical quantity from said measurement data and said additional measurement data; wherein said AC capacitance of said nucleotide molecule is determined by said statistical quantity.

41. The machine-readable data storage device of claim 36, wherein said AC capacitance measurement assembly comprises an AC current source and an AC voltage measurement device, said AC voltage measurement device is attached to said first and second electrodes in a parallel connection with said AC current source, said program comprises the step of instructing said AC current source to apply said AC current signal across said first and second electrodes, said measurement data is an amplitude of an AC voltage signal across said first and second electrodes, and said AC capacitance is inversely proportional to said amplitude of said AC voltage signal.

42. The machine-readable data storage device of claim 36, wherein said AC capacitance measurement assembly comprises an AC voltage source and an AC current measurement device, said AC current measurement device is attached to said first and second electrodes in a series connection with said AC voltage source, said program comprises the step of instructing said AC current source to apply a voltage signal across said first and second electrodes, said measurement data is an amplitude of an AC current signal through said AC current measurement device, and said AC capacitance is proportional to said amplitude of said AC current signal.

43. The machine-readable data storage device of claim 36, wherein said program further comprises the step of instructing said processor device to determine a probability for said nucleotide base being an adenine, a probability for said nucleotide base being a cytosine, a probability for said nucleotide base being a guanine, and a probability for said nucleotide base being a thymine or a uracil.
